(19) United States
(12) Patent Application Publication
(10) Pub. No.: US 2024/0147621 A1
(43) Pub. Date: May 2, 2024

(54) METHOD FOR MANUFACTURING CIRCUIT SUBSTRATE, AND ELECTRONIC DEVICE

(71) Applicant: HITACHI ASTEMO, LTD., Hitachinaka-shi, Ibaraki (JP)

(72) Inventors: Narutoshi YAMADA, Hitachinaka-shi, Ibaraki (JP); Yuuichi YANAGISAWA, Hitachinaka-shi, Ibaraki (JP); Takahiro MAKIKO, Hitachinaka-shi, Ibaraki (JP)

(73) Assignee: HITACHI ASTEMO, LTD., Hitachinaka-shi, Ibaraki (JP)

(21) Appl. No.: 18/547,107

(22) PCT Filed: Dec. 1, 2021
(86) PCT No.: PCT/JP2021/044084

§ 371 Date: Aug. 18, 2023

(30) Foreign Application Priority Data
Mar. 12, 2021 (JP) 2021-040282

(51) Int. Cl. H05K 1/11; B23K 1/005; H05K 3/34; H05K 3/40

(52) U.S. Cl. CPC H05K 1/116; B23K 1/005; H05K 3/3447; H05K 3/4007; B23K 2101/42; H05K 2201/0939

(57) ABSTRACT

A manufacturing method of a circuit board including an annular land portion around a through hole through which a terminal that is an object of a soldering penetrates, and that is soldered on the land portion by a soldering process with a solder supply, the manufacturing method includes: previously forming a preliminary solder at a position opposite to a supply position of the solder in the land portion with respect to the through hole before the soldering process.

### TECHNICAL FIELD

This invention relates to a manufacturing method of a circuit board configured to solder a terminal penetrating through a through hole, to a land portion around the through hole by a soldering process with a solder supply, and an electronic device using this circuit board.

### BACKGROUND ART

In a circuit board of various electronic devices, for example, an electronic component having a relatively small size can be surface-mounted by using a reflow soldering technology. However, the terminal of the connector and the terminal of the electronic component having the relatively large size are soldered, respectively, to an annular land portion around the through hole by using the technology of the laser soldering with the solder supply, and the iron soldering.

For example, in the laser soldering of the terminal, the wire-shaped solder material sent onto the land portion is heated and melted by the irradiation of the laser to form a fillet covering the land portion with the terminal.

However, in the soldering of the terminal penetrating through the through hole, the terminal exists at the central portion of the annular land portion. Accordingly, the heating by the laser and the iron, and the supply of the solder material are performed on one side of the annular land portion with respect to the through hole.

Accordingly, when the heating by the laser and the iron is insufficient, the solder material is not sufficiently supplied (spread) in the opposite portion of the land portion, so that the metal of the land portion is directly exposed. On the other hand, when the heating amount is increased so that the solder material is sufficiently supplied to the opposite portion of the land portion, the board is easy to be burnt by the excessive temperature increase of the land portion.

A patent document 1 discloses a soldering method in which a preliminary solder is formed on the circuit board to close the through hole in addition of the laser soldering with the solder supply, and in which the terminal of the electronic component is inserted in a state in which the preliminary solder is melted by the irradiation of the laser beam. However, this technology cannot dissolve the above-described problems of the laser soldering and the soldering by the iron with the solder supply.

### PRIOR ART DOCUMENT

### Patent Document

Japanese Patent Application Publication No. S59-191397

### SUMMARY OF THE INVENTION

In one aspect according to the present invention, a manufacturing method of a circuit board including an annular land portion around a through hole through which a terminal that is an object of a soldering penetrates, and that is soldered on the land portion by a soldering process with a solder supply, the manufacturing method comprises: previously forming a preliminary solder at a position opposite to a supply position of the solder in the land portion with respect to the through hole before the soldering process.

In the present invention, in the soldering process with the solder supply, the preliminary solder positioned on the side opposite to the solder supply position is melted and spread on the land portion. Accordingly, it is possible to suppress the exposure of the metal of the land portion in the region on the side opposite to the solder supply position. Moreover, the heating capacity of the land portion is increased by the preliminary solder. Consequently, it is difficult to generate the burning of the board.

### BRIEF DESCRIPTION OF DRAWINGS

FIG. 1 is an exploded perspective view showing an electric actuator device for a power steering device to which the present invention is applied.

FIG. 2 is a plan view showing a circuit board.

FIG. 3 is an explanation view of a laser soldering process by using a preliminary solder.

FIG. 4 is a perspective view showing a land portion with the preliminary solder.

FIG. 5A is an explanation view of the laser soldering process to a first land portion. FIG. 5B is an explanation view of the laser soldering process to a second land portion.

FIG. 6 is a plan view showing the land portion in which the preliminary solders are provided on both sides in a major axis direction.

FIG. 7 is a process explanation view of the electric actuator according to the one embodiment.

### DESCRIPTION OF EMBODIMENTS

Hereinafter, one embodiment according to the present invention is explained in detail with reference to the drawings.

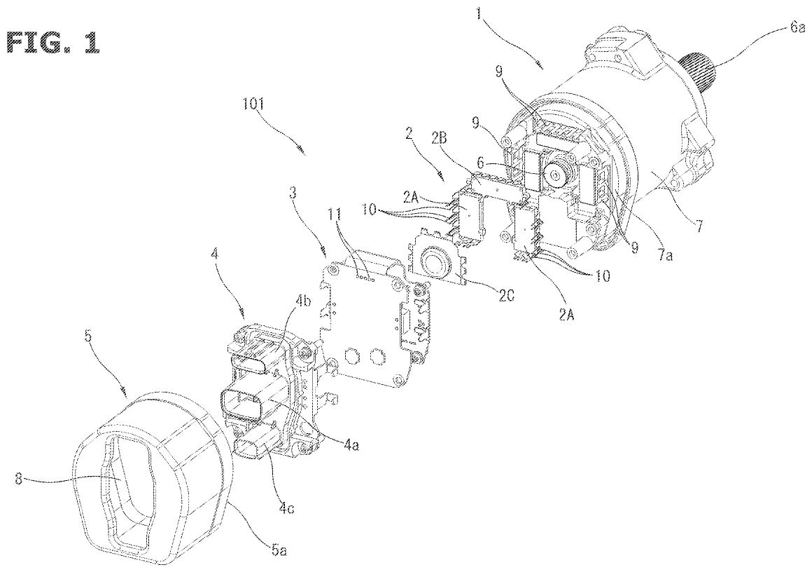

Firstly, one example of an object to which a manufacturing method according to the present invention is applied is briefly explained. In the embodiment, the present invention is applied to an electric actuator device 101 of an electric power steering device of a vehicle which is shown in FIG. 1. Besides, a basic configuration of this electric actuator device 101 is disclosed in, for example, Japanese Patent Application Publication No. 2020-148639. Accordingly, the only minimum explanation is performed.

FIG. 1 is an exploded perspective view showing the electric actuator device 101 configured to provide a steering assist force to a steering mechanism (not shown) in the electric power steering device. This electric actuator device 101 includes a cylindrical motor section 1; an inverter/power module 2; a circuit board (circuit substrate) 3 constituted by a multilayer circuit board bent into a substantially U-shape; a connector member 4 constituted by integrally collecting a plurality of connectors; and a motor cover 5 mounted to one end portion of the motor section 1 to cover the inverter/power module 2, the circuit board 3, and the connector member 4.

The motor section 1 is constituted by a three-phase alternating current motor received within a cylindrical housing 7. The motor section 1 includes a connection portion 6a which is a gear, a spline or so on, and which is provided at a tip end of a rotation shaft 6 protruding from a tip end surface of the housing 7. The motor section 1 is connected through this connection portion 6a to the steering mechanism. The motor is a three phase permanent magnet type blushless motor. A stator includes three phase coils. Permanent magnets are disposed on an outer circumference surface of a rotor. Moreover, the motor includes coils of two systems and corresponding permanent magnets so as to have redundancy.

One end portion of the housing 7 which is on an opposite side of the connection portion 6a constitutes a bottom wall portion 7a which has a horseshoe outline by a part of an outer circumference edge extending in the radial direction. The motor cover 5 having a horseshoe outline corresponding to that of the bottom wall portion 7a is mounted to cover the bottom wall portion 7a. The inverter/power module 2, the circuit board 3, and the connector member 4 are stacked and received in an axial direction of the rotation shaft 6 within a space between the bottom wall portion 7a and the motor cover 5. In this case, both end portions of the coils of the motor penetrate through the bottom wall portion 7a, and protrude toward the motor cover 5 side as coil end portions 9. The both end portions of the coils of the motor are connected to corresponding terminals of the inverter/power module 2 by TIG welding and on.

The inverter/power module 2 includes two inverter modules 2A, and a relay module 2B which is a neutral point relay of the coil. These three modules are disposed in a substantially U shape surrounding the rotation shaft 6. These inverter modules 2A and the relay module 2B are fixed on the end surface of the motor section 1 through a retaining member 2C. Moreover, these inverter modules 2A and the relay module 2B include a plurality of motor driving terminals 10 each having a pin shape. Each of the motor driving terminals 10 extends toward the circuit board 3 along the axial direction of the rotation shaft 6. As described later, each of the motor driving terminals 10 penetrates through a through hole 12 of the circuit board 3. Each of the motor driving terminals 10 is connected and conducted to wirings of the circuit board 3 by laser soldering.

The connector member 4 includes three connectors which are directed in an identical direction along the axial direction of the rotation shaft 6. Specifically, the connector member 4 includes a power supply connector 4a positioned at a central position; a sensor input connector 4b configured to receive signals from sensors (for example, a steering angle sensor, a torque sensor, and so on) disposed on the steering mechanism side; and a communication connector 4c configured to be communicated with other control devices within the vehicle (for example, CAN communication). These connectors 4a, 4b, and 4c protrude from an opening portion 8 of the motor cover 5 to the outside. The sensor input connector 4b includes a plurality of pin-shaped signal terminals which are not shown (hidden) in FIG. 1. These signal terminals extend toward the circuit board 3 along the axial direction of the rotation shaft 6. As described later, each of the signal terminals penetrates through the through hole 12. Then, each of the signal terminals is connected and conducted to the wirings of the circuit board 3 by the laser soldering.

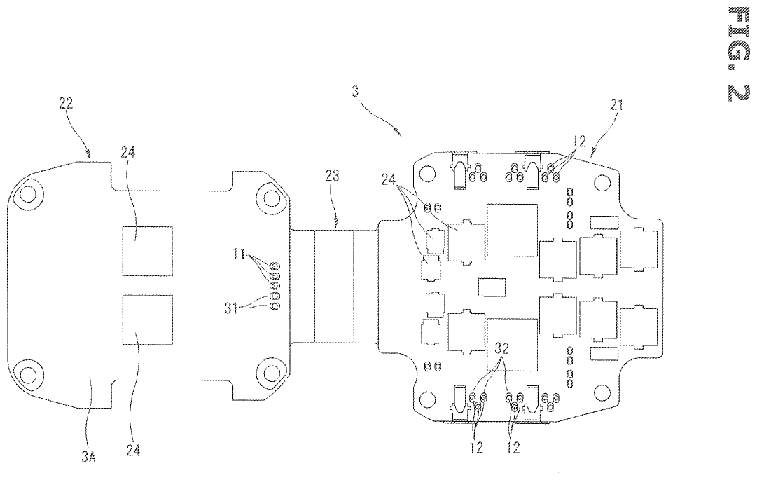

The circuit board 3 has a shape folded into a substantially U-shape. This circuit board 3 is disposed between the bottom wall portion 7a of the housing 7, and the connector member 4. FIG. 2 shows a state in which the circuit board 3 is deployed. The circuit board 3 includes a first rigid portion 21 which is a power substrate mounting electronic components in which the relatively large current flows for driving the motor through the inverter/power module 2; a second rigid portion 22 which is a control substrate mounting control electronic components in which the relatively small current flows; and a flexible portion 23 positioned between the first and second rigid portions 21 and 22. The circuit board 3 is received between the motor cover 5, and the housing 7 which is the case, in a state in which the flexible portion 23 is bent and deformed so that the first rigid portion 21 and the second rigid portion 22 are overlapped with each other in the axial direction of the rotation shaft 6. The first rigid portion 21 and the second rigid portion 22 which are in the folded state are apart from each other by a distance by which the mounted electronic components are not contacted with each other. Moreover, the first rigid portion 21 and the second rigid portion 22 are supported in a state in which the first rigid portion 21 and the second rigid portion 22 keeps a plane state, and in which the first rigid portion 21 and the second rigid portion 22 are parallel with each other.

As shown in FIG. 2, a large number of the electronic components 24 are mainly surface-mounted on a first surface 3A of the circuit board 3 which is an inner side in the folded state, by the reflow soldering. That is, land portions for connecting the electronic components 24 are formed on a surface layer of the circuit board 3 constituted by the multilayer printed board. The cream soldering is printed on these land portions by the print technology using the masking. Then, the electronic components 24 are mounted, respectively, on the predetermined positions. The circuit board 3 is heated in the furnace to melt the solder to perform the soldering. Besides, a part of the electronic components are mounted on a second surface which is the side opposite to the first surface 3A. These are simultaneously reflow-soldered.

The first rigid portion 21 of the circuit board 3 includes circular through holes 12 through which the pin-shaped motor driving terminals 10 extending from the inverter/power module 2 penetrate. An annular land portion 32 is formed around each of the through holes 12. The second rigid portion 22 of the circuit board 3 includes circular through holes 11 through which the signal terminals (not shown) extending from the sensor input connector 4b penetrate. An annular land portion 31 is formed around each of the through holes 11. Hereinafter, the former is referred to as the second land portions 32, and the latter is referred to as the first land portions 31 so as to distinguish these.

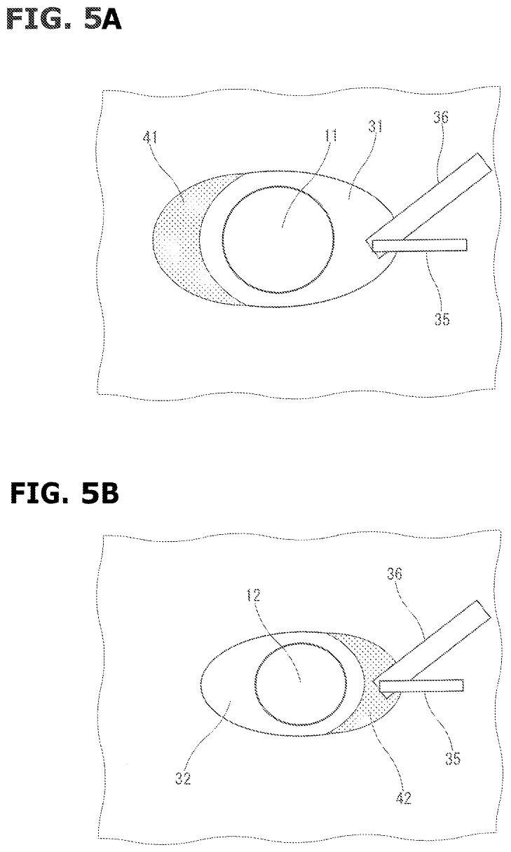

As shown in FIGS. 5A-5B, each of the first land portions 31 and the second land portions 32 has an elliptical shape around one of the through holes 11 and 12. FIG. 5A shows the first land portion 31 surrounding the through hole 11 for the signal terminal. FIG. 5B shows the second land portion 32 surrounding the through hole 12 for the motor driving terminal 10. As is evident from the comparison between these drawings, the first land portion 31 (corresponding to a first land portion in claims) has an area relatively greater than an area of the second land portion 32 (corresponding to a second land portion in claims).

The signal terminals and the motor driving terminals 10 which penetrate through the through holes 11 and 12 are soldered to the first land portions 11 and the second land portions 32 by the laser soldering process with the supply of the solder. In the laser soldering process, as shown in the drawings, a tip end portion of the wire-shaped solder material sent onto the land portions 31 and 32 is heated and melted by the irradiation of the laser beam 36 to form a fillet covering the land portions 31 and 32 with the terminals.

Each of the first land portions 31 and the second land portions 32 has the ellipse shape. This is because the solder material 35 is surely supplied to the land surfaces in the laser soldering process even when there is the product error and the facility (equipment) error. Besides, in the present invention, the “ellipse shape” is not limited to an ellipse shape based on the exact mathematical definition. The “ellipse shape” widely includes an oval shape, a rugby ball shape, and so on.

As shown in FIGS. 5, in the laser soldering process, the solder material 35 is supplied to one sides of the major axis directions of the land portions 31 and 32 around the through holes 11 and 12. The laser beam 36 is irradiated to the tip end portion of the wire-shaped solder material 35.

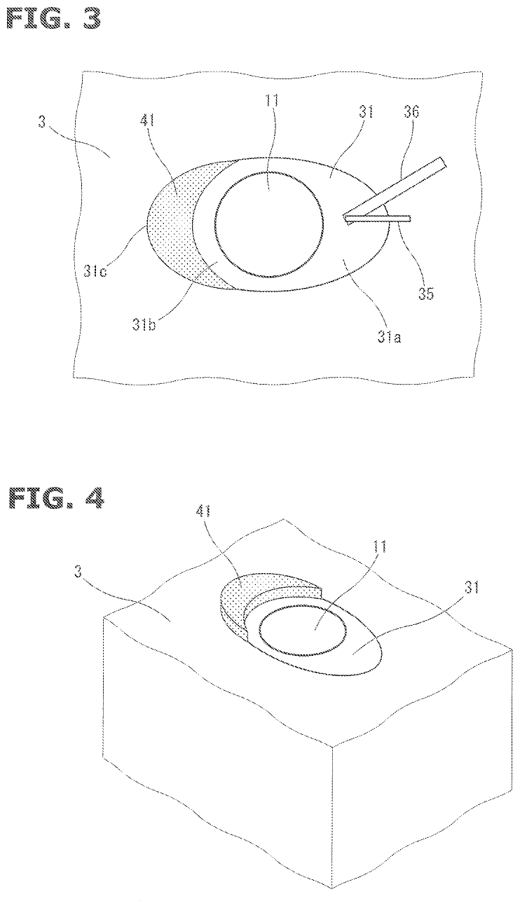

FIG. 4 shows a preliminary solder 41 previously provided to the first land portion 31 before the laser soldering process. FIG. 3 shows the laser soldering process with respect to the first land portion 31 with this preliminary solder 41. As described above, the solder material 35 (also called a main solder to distinguish the preliminary solder) is supplied to one side in the major axis direction of the first lad portion 31 having the ellipse shape. Moreover, the laser beam 36 is irradiated.

As shown in FIGS. 3 and 4, the preliminary solder 41 is formed at a position opposite to the supply position of the solder material 35 with respect to the through hole 11 (to sandwich the through hole 11). That is, in a case in which the land portion 31 is divided into a first portion 31a on a first side, and a second portion 31b on a second side, with respect to the through hole 11, the solder material 35 is supplied to the first portion 31a, and the preliminary solder 41 is provided within the second portion 31b. In the one embodiment, the preliminary solder 41 is formed to cover a substantially crescent region including an end portion 31c of the major axis direction of the ellipse shape of the first land portion 31. Accordingly, the preliminary solder 41 is formed to include a portion (in this example, the end portion 31c) are farthest from the supply position of the solder material 35 in the first land portion 31.

Moreover, the preliminary solder 41 is formed at a position slightly apart from the opening edge of the through hole 11 so that the preliminary solder 41 does not decrease the opening area of the through hole 11.

The preliminary solder 41 provided on the side opposite to the supply position of the solder material 35 in the laser soldering process is melted by receiving the heat in the laser soldering process to form a part of the fillet joined with the terminal. Accordingly, even when the solder material 35 supplied to the first portion 31a is not sufficiently supplied to the second portion 31b on the opposite side, the exposure of the metal surface of the land portion 31 is difficult to be generated, by previously providing the preliminary solder 41. In particular, the preliminary solder 41 is provided to include the end portion 31c farthest from the supply position of the solder material 35. Accordingly, it is possible to suppress the exposure of the metal surface near the end portion 31c. Moreover, the entire heat capacity of the first land portion 31 becomes large by the preliminary solder 41. Consequently, it is possible to suppress the excessive temperature increase of the first land portion 31 due to the irradiation of the laser beam. With this, the burning of the board is difficult to be generated.

In a preferred embodiment, the preliminary solder 41 is simultaneously formed at the reflow soldering for mounting the electronic components 24. That is, as shown in FIG. 3 and FIG. 4, the cream solder is printed on the surface of the first land portion 31 by the print technology using the masking. This cream solder is heated in the reflow process. However, this cream solder does not flow down by the surface tension. The cream solder is cooled and solidified on the first land portion 31. Besides, FIG. 4 strictly shows the shape of the printed cream solder. The shape of the preliminary solder 41 after the heating in the reflow process may have a slightly deformed shape.

Besides, in the present invention, the preliminary solder 41 may be formed in a process other than the reflow soldering for mounting the electronic components 24. That is, the forming means of the preliminary solder 41 may be any means.

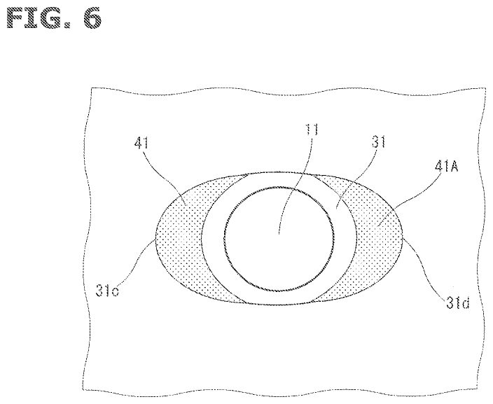

Moreover, as shown in FIG. 6, the preliminary solder 41 may be provided on both sides of first land portion 31 having the ellipse shape in the major axis direction. That is, in the embodiment of FIG. 6, a second preliminary solder 41A is additionally provided to cover the crescent region including the end portion 31d of the first portion 31a of the first land portion 31 in the major axis direction. For example, the second preliminary solder 41A is formed by the print of the cream soldering for the reflow soldering, similarly to the preliminary solder 41. Besides, the second preliminary solder 41A is formed at a position slightly apart from the opening edge of the through hole 11. In this case, in the laser soldering process, the soldering is performed by the irradiation of the laser beam 36 while supplying the solder material 35 on the second preliminary solder 41A.

The second preliminary solder 41A serves for the increase of the heat capacity of the first land portion 31, and the suppression of the board burning in the laser soldering process.

Next, as shown in FIG. 5B, in the second land portion 32 having the area relatively smaller than the area of the first land portion 31, the preliminary solder 42 is provided on the side identical to the supply position of the solder material 35 with respect to the through hole 12. That is, in a case in which the land portion 32 is divided into a first portion 32a on a first side, and a second portion 32b on a second side, with respect to the through hole 12, the preliminary solder 42 is provided in the first portion 32a which is the side identical to the supply position of the solder material 35. In the one embodiment, the preliminary solder 42 is formed to cover a substantially crescent region including the one end portion of the second land portion 32 in the major axis direction of the ellipse shape.

The preliminary solder 42 in this second land portion 32 mainly serves for the increase of the heat capacity of the second land portion 32, similarly to the above-described second preliminary solder 41A in FIG. 6. Accordingly, it is possible to suppress the temperature increase of the second land portion 32 when the laser beam 36 is irradiated, and to suppress the burning of the board.

The second land portion 32 has the relatively small size. Accordingly, the exposure of the metal surface is difficult to be generated even when the preliminary solder does not exist on the side opposite to the supply position of the solder material 35. Besides, the preliminary solder may be provided on the both sides of the second land portion 32 having the ellipse shape in the major axis direction.

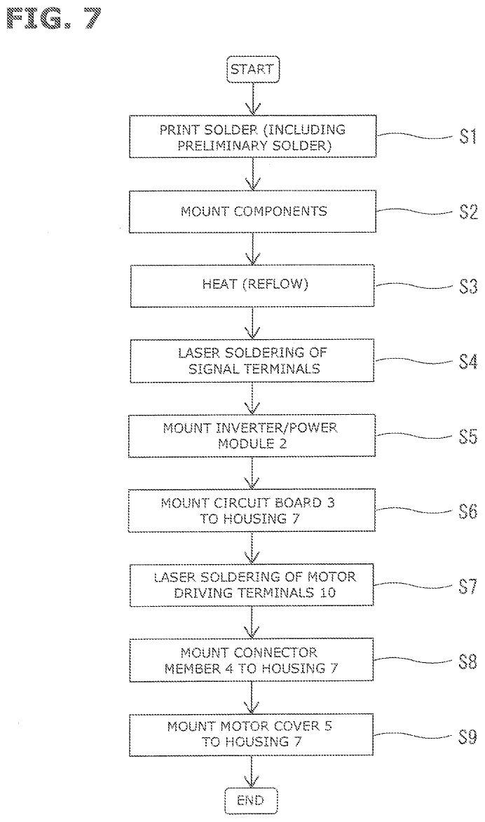

Next, the outline of the manufacturing process of the electric actuator device 101 including the soldering process of the circuit board 3 is explained with reference to a flowchart of FIG. 7. Firstly, at step 1, the cream soldering is printed on the circuit board 3 on which a predetermined wiring pattern is formed. In this case, the cream soldering is printed, by using the masking, on a portion which is an object of the reflow soldering of the electronic component 24, and the forming region of the preliminary solder 41 and 42 in the circuit board 3. Next, at step 2, the electronic components 42 are mounted on the print portion of the cream solder which is the object of the reflow soldering. Next, at step 3, the circuit board 3 on which the electronic components 24 are mounted is heated in the furnace to perform the reflow soldering. With this, the circuit board 3 on which the various electronic components 24 are mounted is formed.

Next, at step 4, the circuit board 3 and the connector member 4 are combined. The pin-shaped signal terminals (not shown) extending from the sensor input connector 4b are inserted into the through holes 11 of the circuit board 3. Then, the signal terminals are laser-soldered to the first land portion 31. This soldering is performed while the solder material 35 is supplied by using the soldering robot.

Next, at step 5, the inverter/power module 2 (the inverter module 2A, and the relay module 2B) is mounted to the housing 7. In this case, the terminals of the inverter/power module 2 are TIG-welded to the coil terminal portion 9.

Next, at step 6, the circuit board 3 is mounted to the housing 7 through the screws. In this case, the pin-shaped motor driving terminals 10 of the inverter/power modules 3 are inserted into the through holes 12 of the circuit board 3.

Next, at step 7, the motor driving terminals 10 penetrating through the through holes 12 are laser-soldered to the second land portions 32 around the through holes 12. This soldering is performed while the solder material 35 is supplied by using the soldering robot.

Next, at step 8, the connector member 4 is fixed to the housing 7 through the screws. The circuit board 3 is positioned between the housing 7 and the connector member 4.

Finally, at step S9, the motor cover 5 is mounted to the housing 7. With this, the electric actuator device 101 is finished.

Hereinabove, this invention is explained based on the laser soldering as the example. However, the present invention is not limited to the laser soldering. The present invention is applicable to the soldering with the supply of the solder material (the main solder).

Moreover, the present invention is not limited to the land portion having the ellipse shape. The present invention is applicable to the land portion having any shape, and surrounding the through hole.

As described above, in the present invention, a manufacturing method of a circuit board including an annular land portion around a through hole through which a terminal that is an object of a soldering penetrates, and that is soldered on the land portion by a soldering process with a solder supply, the manufacturing method includes: previously forming a preliminary solder at a position opposite to a supply position of the solder in the land portion with respect to the through hole before the soldering process.

In a preferable aspect according to the present invention, the land portion is formed into an ellipse shape; and the preliminary solder is formed in a region which is on the side opposite to the supply position of the solder with respect to the through hole, and which includes a first end portion in a major axis direction of the ellipse shape.

In another preferable aspect according to the present invention, the preliminary solder is formed in a second region including a second end portion in the major axis direction of the ellipse shape.

In still another preferable aspect according to the present invention, the preliminary solder is formed to includes a portion farthest from the supply position of the solder in the land portion.

In still another preferable aspect according to the present invention, the circuit board includes the annular land portions of a first land portion having a relatively large area, and a second land portion having a relatively small area; in the first land portion, the preliminary solder is previously formed at the position opposite to the supply position of the solder with respect to the through hole; and in the second land portion, the preliminary solder is previously formed at a position on the supply position side of the solder with respect to the through hole.

In a concrete preferable aspect according to the present invention, the soldering process is a laser soldering.

In a preferable aspect according to the present invention, the solder is printed and formed on a portion which is an object of a reflow soldering, and a forming region of the preliminary solder in the circuit board; an electronic component is mounted on the portion which is the object of the reflow soldering; and the soldering process is performed to the terminal disposed in the through hole.

Moreover, in the present invention, an electronic device including a circuit board on which a plurality of electronic components are mounted, and which includes a through hole through which a terminal of a connecter penetrates, the terminal being soldered on an annular land portion surrounding the through hole, the electronic device includes: a fillet of the land portion which includes a preliminary solder made of a material identical to a material of the solder for a surface mounting of the electronic component, and a main solder supplied at the soldering of the terminal of the connector, the preliminary solder and the main solder being disposed on opposite sides with respect to the through hole.

1. A manufacturing method of a circuit board including an annular land portion around a through hole through which a terminal that is an object of a soldering penetrates, and that is soldered on the land portion by a soldering process with a solder supply, the manufacturing method comprising:
previously forming a preliminary solder at a position opposite to a supply position of the solder in the land portion with respect to the through hole before the soldering process.

2. The manufacturing method of the circuit board as claimed in claim 1, wherein the land portion is formed into an ellipse shape; and
the preliminary solder is formed in a region which is on the side opposite to the supply position of the solder with respect to the through hole, and which includes a first end portion in a major axis direction of the ellipse shape.

3. The manufacturing method of the circuit board as claimed in claim 2, wherein the preliminary solder is formed in a second region including a second end portion in the major axis direction of the ellipse shape.

4. The manufacturing method of the circuit board as claimed in claim 1, wherein the preliminary solder is formed to includes a portion farthest from the supply position of the solder in the land portion.

5. The manufacturing method of the circuit board as claimed in claim 1, wherein the circuit board includes the annular land portions of a first land portion having a relatively large area, and a second land portion having a relatively small area;
in the first land portion, the preliminary solder is previously formed at the position opposite to the supply position of the solder with respect to the through hole; and
in the second land portion, the preliminary solder is previously formed at a position on the supply position side of the solder with respect to the through hole.

6. The manufacturing method of the circuit board as claimed in claim 1, wherein the soldering process is a laser soldering.

7. The manufacturing method of the circuit board as claimed in claim 1, wherein the solder is printed and formed on a portion which is an object of a reflow soldering, and a forming region of the preliminary solder in the circuit board;
an electronic component is mounted on the portion which is the object of the reflow soldering; and
the soldering process is performed to the terminal disposed in the through hole.

8. An electronic device including a circuit board on which a plurality of electronic components are mounted, and which includes a through hole through which a terminal of a connecter penetrates, the terminal being soldered on an annular land portion surrounding the through hole, the electronic device comprising:
a fillet of the land portion which includes a preliminary solder made of a material identical to a material of the solder for a surface mounting of the electronic component, and a main solder supplied at the soldering of the terminal of the connector,
the preliminary solder and the main solder being disposed on opposite sides with respect to the through hole.
